(19) United States
(12) Patent Application Publication
(10) Pub. No.: US 2006/0076987 A1
(43) Pub. Date: Apr. 13, 2006

(54) Multi-threshold CMOS system having short-circuit current prevention circuit

(76) Inventor: Hyo-sig Won, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/240,419

(22) Filed: Oct. 3, 2005

(30) Foreign Application Priority Data
Oct. 8, 2004 (KR) 2004-0080357

(51) Int. Cl. H03B 1/00

(52) U.S. Cl. 327/112

(57) ABSTRACT

Disclosed is a multi-threshold complementary metal-oxide semiconductor (MTCMOS) circuit system. The MTCMOS circuit system includes a single control transistor that it uses to switch a MTCMOS circuit between a sleep mode and an active mode. The MTCMOS circuit also includes a short-circuit current prevention circuit controlled by a MTCMOS control circuit. The short-circuit current prevention circuit receives an output signal from the MTCMOS circuit and selectively transmits the output signal to a latch circuit depending on the logic state of a control signal from the MTCMOS control circuit.

### BACKGROUND OF THE INVENTION

1. Field of the Invention

The present invention relates generally to a multi-threshold complementary metal-oxide semiconductor (MTCMOS) circuit. More particularly, the invention relates to a MTCMOS circuit adapted to prevent a short-circuit from forming in an external circuit connected to the MTCMOS circuit when the MTCMOS circuit is in a sleep mode.

This application claims the priority to Korean Patent Application No. 10-2004-0080357 filed on Oct. 8, 2004, the disclosure of which is hereby incorporated by reference in its entirety.

2. Description of the Related Art

A conventional multi-threshold complementary metal-oxide semiconductor (MTCMOS) circuit has a configuration in which control transistors are connected in series between a power source and a logic circuit. Typically, the control transistors have threshold voltages that are higher than threshold voltages of field effect transistors contained in the logic circuit. The MTCMOS circuit reduces the power consumption in the logic circuit by selectively disconnecting the power source from the- logic circuit using the control transistors.

FIG. 1 is a circuit diagram for a conventional MTCMOS circuit 100.

Referring to FIG. 1, MTCMOS circuit 100 includes a logic circuit 110 connected between a node having a virtual power source voltage VVDD and a node having a virtual ground voltage VGND. MTCMOS circuit 100 further includes a first control transistor Q1 connected between a power source providing a power source voltage VDD and the node having virtual power source voltage VVDD, and a second control transistor Q2 connected between ground, i.e. a ground voltage GND, and the node having virtual ground voltage VGND. First control transistor Q1 and second control transistor Q2 perform switching operations for MTCMOS circuit 100.

First and second control transistors Q1 and Q2, which have high threshold voltages Vth relative to field effect transistors in logic circuit 110, are respectively connected in series between the power source and logic circuit 110 and between ground and logic circuit 110. Where logic circuit 110 is in an active mode, i.e., when it is operating, one of first and second control transistors Q1 and Q2 is turned on in response to respective control signals \overline{SL} and SL. Accordingly, power source voltage VDD or ground voltage GND is supplied to logic circuit 110. Where logic circuit 110 is in a sleep mode, i.e. when it is not being used, control transistors Q1 and Q2 are turned off to disconnect logic circuit 110 from the power source and from ground, thereby reducing leakage current occurring in logic circuit 110 and minimizing the power consumption of the entire system.

Thus, as is conventionally understood, MTCMOS circuit 100 is capable of reducing overall power consumption within the operational context of a large scale integrated (LSI) circuit by using a sleep mode having a longer cycle that an associated active mode. However, this capability requires the inclusion of control transistors Q1 and Q2, which increases the size of the circuit. In addition, where control transistors Q1 and Q2 are turned off, virtual power source voltage VVDD or virtual ground voltage VGND floats. As a result, an output of MTCMOS circuit 100 also floats. Accordingly, in cases where the output of MTCMOS circuit 100 is connected to another circuit, such as circuit 200 in FIG. 1, and where circuit 200 remains in an active state during sleep mode states of MTCMOS circuit 100, a short-circuit current may be formed.

Due to at least the above shortcomings noted in the conventional MTCMOS circuit, a MTCMOS circuit having decreased size is desired. Further, an improved MTCMOS circuit is required which prevents formation of a short circuit when a floating output state of the circuit is connected to an active external circuit.

### SUMMARY OF THE INVENTION

In one aspect, the present invention provides a MTCMOS circuit system in which the size of a MTCMOS circuit is minimized. In a further aspect, the present invention provides a MTCMOS circuit system having an isolated output in relation to a connected external circuit when the MTCMOS circuit is in a sleep mode.

According to one embodiment of the present invention, a multi-threshold complementary metal-oxide semiconductor (MTCMOS) circuit system is provided. The system comprises a MTCMOS control circuit and a MTCMOS circuit. The MTCMOS circuit transitions between an active mode and a sleep mode in response to signals generated by the MTCMOS control circuit. The MTCMOS circuit comprises a logic circuit including a plurality of field effect transistors, a power source providing a power source voltage to the logic circuit, a virtual power source voltage apparent at one of a plurality of terminals of the logic circuit, and a control transistor connected between the terminal having the virtual power source voltage and ground. The control transistor has a threshold voltage which is higher than a threshold voltage of the field effect transistors.

According to another embodiment of the present invention, another MTCMOS circuit system is provided. The system comprises a MTCMOS control circuit and a MTCMOS circuit. The MTCMOS circuit transitions between an active mode and a sleep mode in response to signals generated by the MTCMOS control circuit. The MTCMOS circuit comprises a logic circuit including a plurality of field effect transistors, a power source providing a power source voltage to the logic circuit, a virtual power source voltage apparent at one of a plurality of terminals of the logic circuit, a control transistor connected between the terminal having the virtual power source voltage and ground, and a short-circuit current prevention circuit preventing a short-circuit current from occurring in an external circuit connected to the MTCMOS circuit while the MTCMOS circuit is in the sleep mode. Typically, the control transistor has a threshold voltage which is higher than a threshold voltage of the field effect transistors.

According to still another embodiment of the present invention, a method of controlling a MTCMOS circuit is provided. The method comprises using a first control signal to turn a control transistor on and off and using a second control signal to control a short-circuit current protection unit. The method further comprises switching a stop signal to a second logic state in order to place the MTCMOS circuit in a sleep mode, switching the second control signal to the second logic state in response to the stop signal in order to prevent an output of the MTCMOS circuit from being transmitted to a latch unit, and switching the first control signal to a first logic state after a predetermined delay following the switching of the second control signal to the second logic state. Typically, the control transistor is connected between ground and node having a virtual power source voltage. In addition, the control transistor has a threshold voltage which is higher than a threshold voltage of field effect transistors in a logic circuit of the MTCMOS circuit, and the short-circuit current prevention unit prevents a short-circuit current from occurring in an external circuit connected to the MTCMOS circuit while the MTCMOS circuit is in a sleep mode.

### BRIEF DESCRIPTION OF THE DRAWINGS

The invention is described below in relation to several embodiments illustrated in the accompanying drawings. Throughout the drawings like reference numbers indicate like exemplary elements, components, or steps. In the drawings:

FIG. 1 is a circuit diagram of a conventional MTCMOS circuit;

FIG. 2 is a block diagram of a MTCMOS circuit system including a short-circuit current prevention circuit according to an embodiment of the present invention;

FIG. 3 is a circuit diagram of a transmission controlling unit for a MTCMOS circuit in FIG. 2; and,

FIG. 4 is a waveform timing diagram for input and output signals of a MTCMOS control circuit shown in FIG. 2.

### DESCRIPTION OF THE EXEMPLARY EMBODIMENTS

Exemplary embodiments of the invention are described below with reference to the corresponding drawings. These embodiments are presented as teaching examples. The actual scope of the invention is defined by the claims that follow.

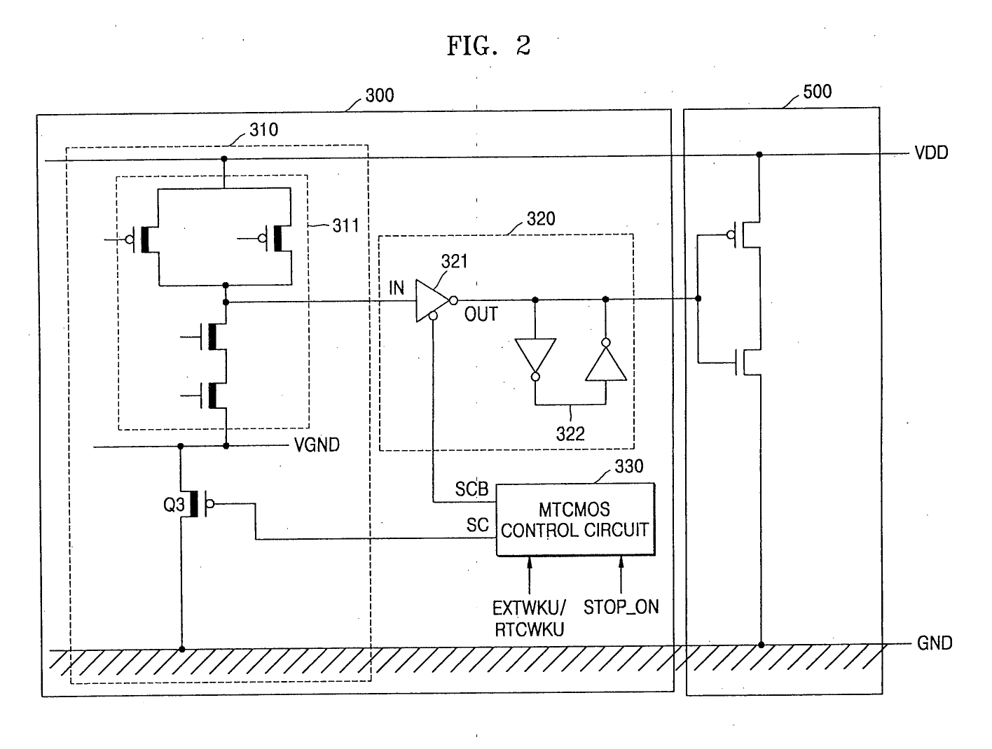

FIG. 2 is a block diagram of a MTCMOS circuit system 300 including a short-circuit current prevention circuit according to an embodiment of the present invention.

Referring to FIG. 2, MTCMOS circuit system 300 includes a MTCMOS circuit 310, a short-circuit current prevention circuit 320 preventing a short-circuit current from flowing in an external circuit 500, and a MTCMOS control circuit 330 setting a mode (e.g. an active mode or a sleep mode) for MTCMOS circuit 310.

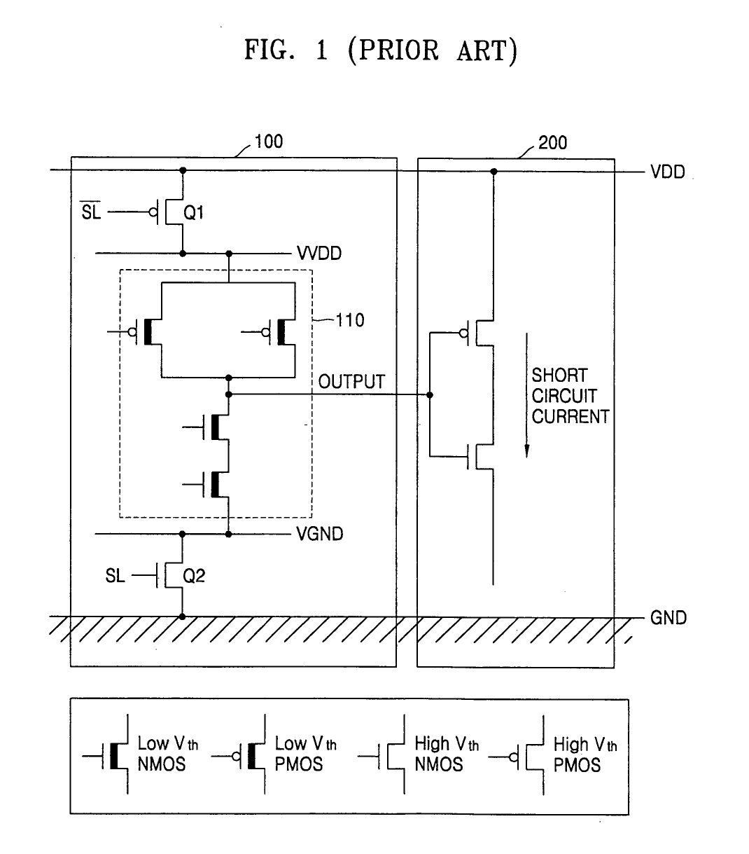

MTCMOS circuit 310 comprises a logic circuit 311 connected between a power source providing a power source voltage VDD and a node having a virtual ground voltage VGND. MTCMOS circuit 310 further comprises a control transistor Q3 connected between the node having virtual ground voltage VGND and ground, i.e. a ground voltage GND. Control transistor Q3 is switched on and off in response to a first control signal SC output by MTCMOS control circuit 330. In contrast to the conventional MTCMOS circuit shown in FIG. 1, an additional transistor does not need to be connected between power source voltage and logic circuit 311. By omitting this transistor, the size of MTCMOS circuit 310 is substantially reduced.

MTCMOS control circuit 330 receives predetermined wake-up signals EXTWKU and RTCWKU and a predetermined stop signal STOP_ON, and outputs a first control signal SC used for switching control transistor Q3 on and off, and a second control signal SCB, which is input to short-circuit current prevention circuit 320 in order to control transmission of an input IN, which is supplied to circuit 500 by MTCMOS circuit 310. The configuration of MTCMOS control circuit 330 is described in further detail in Korean patent application No. 2004-5598, and therefore further description thereof will be omitted.

In cases where MTCMOS circuit 310 is in an active mode, short-circuit current prevention circuit 320 is controlled by control signal SCB to transmit input IN to circuit 500. On the contrary, in cases where MTCMOS circuit 310 is in a sleep mode, short circuit current prevention circuit 230 does not transmit input IN to circuit 500.

Short-circuit current prevention circuit 320 comprises a transmission controlling unit 321 that receives input IN from MTCMOS circuit 310 and second control signal SCB from MTCMOS control circuit 330. Short circuit prevention circuit 320 further comprises a latch unit 322 storing output data OUT output by transmission controlling unit 321. Transmission controlling unit 321 either transmits input IN to latch unit 322 or it prevents input IN from being transmitted to latch unit 322 depending on a logic level of second control signal SCB received from the MTCMOS control circuit 330.

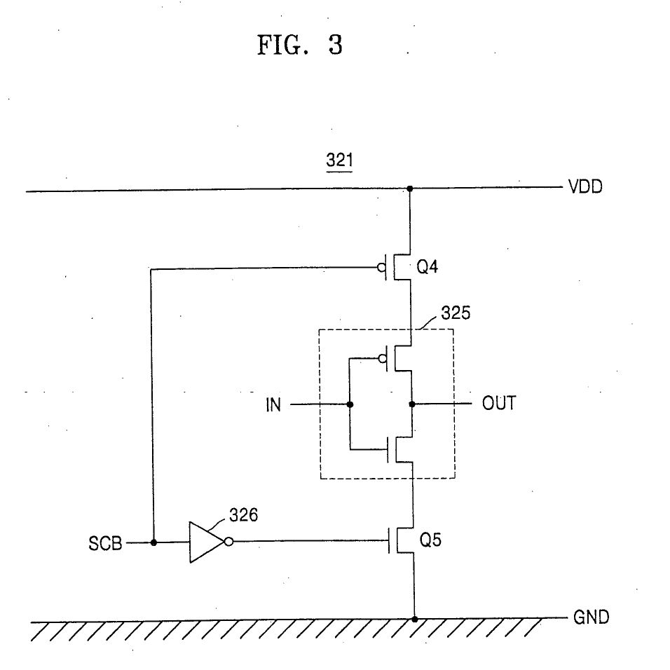

FIG. 3 is a circuit diagram illustrating an embodiment of transmission controlling unit 321.

Referring to FIG. 3, transmission controlling unit 321 comprises an output transmission unit 325 transmitting output data OUT, which is generated in response to input IN received from MTCMOS circuit 310, to latch unit 322, an inverter 326 inverting second control signal SCB output by MTCMOS control circuit 330, and first and second transistors Q4 and Q5, respectively controlling the supply of power source voltage VDD and ground voltage GND to the transmission controlling unit.

First transistor Q4 has a gate to which second control signal SCB is applied, a source connected to power source voltage VDD, and a drain connected to a first node of output transmission unit 325.

Second transistor Q5 has a gate connected to an output of inverter 326, i.e., inverted control signal SCB, a source connected to ground voltage GND, and a drain connected to a second node of output transmission unit 325.

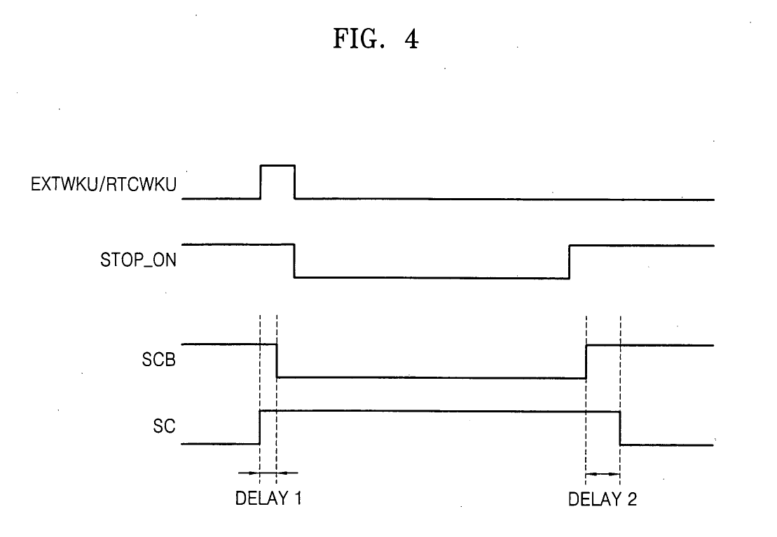

FIG. 4 is a waveform timing diagram illustrating input and output signals of MTCMOS control circuit 330. The timing diagram illustrates timing relationships between wake-up signals EXTWKU and RTCWKU, stop signal STOP_ON input to MTCMOS control circuit 330, and first and second control signals SC and SCB output from the MTCMOS control circuit 330.

The operation of MTCMOS circuit system 300 will now be described with reference to FIGS. 2, 3, and 4.

Where MTCMOS circuit system 300 switches from a sleep mode to an active mode, external wake-up signals EXTWKU and RTCWKU transition from a first logic state (e.g. a logic state “low) to a second logic state (e.g. a logic state “high”). In response to this transition, MTCMOS control circuit 330 changes first control signal SC from the first logic state to the second logic state in order to turn control transistor Q3 on. Then, after a first delay DELAY1, MTCMOS control circuit 330 switches second control signal SCB from the second logic state to the first logic state in order to control short-circuit current prevention circuit 320. Thereafter, predetermined stop signal STOP_ON is switched from the second logic state to the first logic state.

Once first control signal SC is in the second logic state, control transistor Q3 is turned on to supply current to logic circuit 311. Accordingly, MTCMOS circuit 310 enters the active mode, and input IN, which is output by logic circuit 311, is input to output transmission unit 325 of transmission controlling unit 321. After first delay DELAY1 occurs and second control signal SCB switches to the first logic state, first and second transistors Q4 and Q5 are turned on. As a result, output transmission unit 325 latches input IN, received from logic circuit 311, in latch unit 322, and output data OUT previously stored in latch unit 322 is input to circuit 500.

Where MTCMOS circuit 310 changes from the active mode to the sleep mode, wake-up signals EXTWKU and RTCWKU remain in the first logic state and predetermined stop signal STOP_ON, which instructs MTCMOS circuit 310 to enter a sleep mode, transitions from the first logic state to the second logic state. Then, MTCMOS control circuit 330, which receives stop signal STOP_ON, switches second control signal SCB from the first logic state to the second logic state. Then, after a second delay DELAY2, MTCMOS control circuit 330 switches first control signal SC from the second logic state to the first logic state.

Once second control signal SCB enters the second logic state, first transistor Q4 and second transistor Q5 are turned off. After second delay DELAY2, first control signal SC enters the first logic state, control transistor Q3 is turned off, and MTCMOS circuit 310 enters the sleep mode. Where control transistor Q3 is turned off, input IN from MTCMOS circuit 310 floats. However, since first transistor Q4 and second transistor Q5 are turned off, the supply of power source voltage VDD and ground voltage GND to output transmission unit 325 is interrupted and therefore output data OUT is not transmitted to latch unit 322.

As a result, data stored in latch unit 322 during a previous active mode is input to circuit 500, rather than the current output of the MTCMOS circuit 310, which is floats during the sleep mode. Because of this, a short-circuit current is prevented from occurring in circuit 500.

According to the present invention, a MTCMOS circuit system includes only one control transistor for controlling the operation of a MTCMOS circuit, thereby limiting the size of the MTCMOS circuit. In addition, the MTCMOS circuit prevents an output of the MTCMOS circuit, which floats when the MTCMOS circuit is in a sleep mode, from being transmitted to another circuit, thereby ensuring stable operation of the MTCMOS circuit system.

The foregoing preferred embodiments are teaching examples. Those of ordinary skill in the art will understand that various changes in form and details may be made to the exemplary embodiments without departing from the scope of the present invention which is defined by the following claims.

What is claimed:

1. A multi-threshold complementary metal-oxide semiconductor (MTCMOS) circuit system, the system comprising:
a MTCMOS circuit comprising an output terminal and adapted to transition between an active mode and a sleep mode in response to control signals generated by a MTCMOS control circuit, wherein the MTCMOS circuit comprises:
a logic circuit comprising a plurality of field effect transistors characterized by a threshold voltage, and comprising a plurality of terminals, wherein one of the plurality of terminals has a virtual power source voltage; and,
a control transistor connected between ground and the one terminal having the virtual power source voltage;
wherein the control transistor has a threshold voltage higher than the threshold voltage.

2. The MTCMOS circuit system of claim 1, further comprising:
a short-circuit current prevention circuit connected between the output terminal of the MTCMOS circuit and an input terminal of an external circuit.

3. The MTCMOS circuit system of claim 2, wherein the control signals generated by the MTCMOS control circuit comprise:
a first control signal switching the control transistor in accordance with either the active mode or the sleep mode of the MTCMOS circuit; and,
a second control signal controlling the short-circuit current prevention circuit.

4. The MTCMOS circuit system of claim 3, wherein the short-circuit current prevention circuit comprises:
a transmission controlling unit receiving the second control signal and a signal from the output terminal of the MTCMOS circuit; and,
a latch unit connected between an output of the transmission controlling unit and the external circuit.

5. The MTCMOS circuit system of claim 4, further comprising:
a power source connected to another one of the plurality of terminals;
wherein the transmission controlling unit comprises:
an output transmission unit transmitting data generated by the MTCMOS circuit to the latch unit;
a first transistor having a source connected to the power source, a drain connected to a first node of the output transmission unit, and a gate receiving the second control signal; and,
a second transistor having a source connected to ground, a drain connected to a second node of the output transmission unit, and a gate receiving a signal derived from the second control signal.

6. The MTCMOS circuit system of claim 5, wherein the transmission controlling unit turns off the first and second transistors to disconnect the output transmission unit from the power source and ground.

7. The MTCMOS circuit system of claim 2, wherein the MTCMOS control circuit causes the MTCMOS circuit to transition to the active mode in response to predetermined wake-up signals and causes the MTCMOS circuit to transition to the sleep mode in response to a predetermined stop signal.

8. The MTCMOS circuit system of claim 7, wherein the control signals generated by the MTCMOS control circuit comprise:
a first control signal switching the control transistor in accordance with either the active mode or the sleep mode; and,
a second control signal controlling the short-circuit current prevention circuit.

9. The MTCMOS circuit system of claim 2, wherein the external circuit remains in an active state even when the MTCMOS circuit enters a sleep mode.

10. A method of controlling a multi-threshold complementary metal-oxide semiconductor (MTCMOS) circuit comprising a logic circuit connected to a power source, a control transistor connected between the logic circuit and ground, and a short-circuit prevention circuit connected between the power source and ground by respective first and second transistors, the method comprising:
switching the control transistor using a first control signal; and,
switching the first and second transistors using a second control signal.

11. The method of claim 10, wherein switching the control transistor using the first control signal comprises:
switching the first control signal from a first logic state to a second logic state in response to a predetermined wake up signal transitioning from the first logic state to the second logic state; and,
switching the first control signal from the second logic state to the first logic state following a predetermined delay after the second control signal has switched from the first logic state to the second logic state in response to a stop signal transitioning from the first logic state to the second logic state.

12. The method of claim I 1, wherein the predetermined wake up signal and the stop signal are generated by a MTCMOS control circuit.

13. The method of claim I 1, wherein switching the first control signal from the first logic state to the second logic state connects the logic circuit to ground; and,
switching the first control signal from the second logic state to the first logic state disconnects the logic circuit from ground.

14. The method of claim 10, wherein switching the first and second transistors using a second control signal comprises:
switching the second control signal from a second logic state to a first logic state following a predetermined delay after the first control signal has switched from the first logic state to the second logic state in response to a predetermined wake up signal; and,
switching the second control signal from the first logic state to the second logic state in response to a stop signal.

15. The method of claim 14, wherein the predetermined wake up signal and the stop signal are generated by a MTCMOS control circuit.

16. The method of claim 14, wherein switching the second control signal from the first logic state to the second logic state disconnects the short-circuit prevention circuit from the power source and from ground; and,
switching the second control signal from the second logic state to the first logic state connects the short-circuit prevention circuit to the power source and to ground.

17. The method of claim I 1, wherein the control transistor and the first and second transistors are turned on to place the MTCMOS circuit in an active mode; and,
the control transistor and the first and second transistors are turned off to place the MTCMOS circuit in a sleep mode.

18. A method of operating a multi-threshold complementary metal-oxide semiconductor (MTCMOS) circuit comprising a logic circuit connected to a power source, a control transistor connected between the logic circuit and ground, and a short-circuit prevention circuit connected between the power source and ground by respective first and second transistors, the method comprising:
providing a predetermined wake up signal and a stop signal to a MTCMOS control circuit supplying a first control signal and a second control signal;
switching the first control signal from a first logic state to a second logic state in response to a transition of the predetermined wake up signal from the first logic state to the second logic state;
switching the second control signal from the second logic state to the first logic state following a first predetermined delay after the first logic signal has transitioned from the first logic state to the second logic state;
transmitting an output signal from the logic unit to an external circuit via a transmission controlling unit in the short-circuit prevention circuit; and,
latching the output signal from the logic unit with a latch contained in the short-circuit prevention circuit.

19. The method of claim 18, further comprising:
switching the second control signal from the first logic state to the second logic state in response to a transition of the stop signal from the first logic state to the second logic state;
switching the first control signal from the second logic state to the first logic state following a second predetermined delay after the second logic signal has transitioned from the first logic state to the second logic state;
disconnecting the output signal from the logic unit from the external circuit by turning off the first and second transistors in the short-circuit prevention circuit with the second control signal, thereby disconnecting the short-circuit prevention circuit from the power source and ground, respectively; and,
disconnecting the logic circuit from ground by turning off the control transistor with the first control signal.

20. The method of claim 19, wherein the transition of the predetermined wake up signal from the first logic state to the second logic state causes the MTCMOS circuit to assume an active mode; and,
the transition of the stop signal from the first logic state to the second logic state causes the MTCMOS circuit to assume a sleep mode.
